(19) United States
(12) Patent Application Publication
(10) Pub. No.: US 2026/0040944 A1
(43) Pub. Date: Feb. 5, 2026

(54) SEMICONDUCTOR PACKAGE AND METHOD OF FABRICATING THE SAME

(71) Applicant: SAMSUNG ELECTRONICS CO., LTD., SUWON-SI (KR)

(72) Inventors: Junghoon KANG, Suwon-si (KR); Hyeonjeong HWANG, Suwon-si (KR)

(21) Appl. No.: 19/042,442

(22) Filed: Jan. 31, 2025

(30) Foreign Application Priority Data
Jul. 31, 2024 (KR) 10-2024-0102001

(51) Int. Cl. H01L 23/373; H01L 21/48; H01L 23/00; H01L 23/538; H01L 25/18

(52) U.S. Cl. CPC H01L 23/3735; H01L 21/4882; H01L 23/5384; H01L 24/24; H01L 25/18; H01L 2224/24225

(57) ABSTRACT

A semiconductor package includes: a first redistribution layer including a first wiring; a first semiconductor chip disposed on the first redistribution layer; a post disposed on the first redistribution layer, and electrically connected to the first wiring; a second redistribution layer disposed on the post and including a second wiring and a base metallic layer, wherein the second wiring is electrically connected to the post, and the base metallic layer is disposed on the first semiconductor chip; a marking metallic layer disposed on an upper surface of the base metallic layer; and a heat transfer part disposed on an upper surface of the marking metallic layer and including a thermal interface material (TIM), wherein the marking metallic layer includes a recess that is formed from the upper surface of the marking metallic layer toward the base metallic layer, and the heat transfer part fills the recess.

### CROSS-REFERENCE TO RELATED APPLICATION

This application claims priority under 35 U.S.C. § 119 to Korean Patent Application No. 10-2024-0102001, filed on Jul. 31, 2024, in the Korean Intellectual Property Office, the disclosure of which is incorporated by reference herein in its entirety.

### TECHNICAL FIELD

Embodiments of the present inventive concept relate to a semiconductor package and a method of fabricating the same.

### DISCUSSION OF THE RELATED ART

With development of electronic industry, a demand for electronic components that have increased functionality, increased speed, and a reduction in size is increasing. To respond to such a demand, it is desirable to develop technology that enables the formation of multiple chips in one package, serving as a method for fabricating a high-speed signal transmitting and minimally sized semiconductor device or semiconductor package.

When the multiple chips are formed in the one package, the effective dissipation of heat that is generated therein may have a great influence on performance of a semiconductor. In addition, in a process of fabricating the multiple chips in one package, securing visibility of a laser marking with which information about a semiconductor chip is identifiable in an intermediately fabricated package is considered to be desirable.

### SUMMARY

According to example embodiments of the present inventive concept, a semiconductor package includes: a first redistribution layer including a first wiring; a first semiconductor chip disposed on the first redistribution layer; a post disposed on the first redistribution layer, and spaced apart from the first semiconductor chip in a direction parallel to an upper surface of the first redistribution layer, wherein the post is electrically connected to the first wiring; a second redistribution layer disposed on the post and including a second wiring and a base metallic layer, wherein the second wiring is electrically connected to the post, and the base metallic layer is disposed on the first semiconductor chip; a marking metallic layer disposed on an upper surface of the base metallic layer; and a heat transfer part disposed on an upper surface of the marking metallic layer and including a thermal interface material (TIM), wherein the marking metallic layer includes a recess that is formed from the upper surface of the marking metallic layer toward the base metallic layer, and the heat transfer part fills the recess.

According to example embodiments of the present inventive concept, a semiconductor package includes: a first redistribution layer including a first wiring; a first semiconductor chip disposed on an upper surface of the first redistribution layer; a post disposed on the upper surface of the first redistribution layer, and spaced apart from the first semiconductor chip in a direction parallel to the upper surface of the first redistribution layer, wherein the post is electrically connected to the first wiring; a second redistribution layer disposed on an upper surface of the post and including a second wiring and a base metallic layer, wherein the second wiring is electrically connected to the post, and the base metallic layer is disposed on the first semiconductor chip; and a heat emission part including a protrusion part configured to protrude toward the base metallic layer.

According to example embodiments of the present inventive concept, a semiconductor package fabricating method includes: forming a marking metallic layer on a surface of a glass carrier; forming an upper redistribution layer on a first surface of the marking metallic layer, wherein the upper redistribution layer includes upper wiring and a base metallic layer; forming a semiconductor chip layer on a surface of the upper redistribution layer, wherein the semiconductor chip layer includes a post, a first semiconductor chip, and a molding member; forming a lower redistribution layer that includes lower wiring electrically connected to the upper wiring, the first semiconductor chip, and the post and is disposed on a surface of the semiconductor chip layer; removing the glass carrier with turning the glass carrier upside down so that the glass carrier is positioned above; and forming a recess that extends from a second surface of the marking metallic layer toward the base metallic layer.

### BRIEF DESCRIPTION OF THE DRAWINGS

The above and other aspects and features of the present inventive concept will become more apparent by describing in detail embodiments thereof with reference to the attached drawings, in which:

FIG. 1 is a cross-sectional diagram illustrating an example cross section of a semiconductor package according to example embodiments of the present inventive concept;

FIG. 2 is an enlarged example diagram illustrating part N of FIG. 1;

FIG. 3 is an enlarged example diagram illustrating part M of FIG. 1;

FIG. 4 is an enlarged example diagram illustrating part M of FIG. 1 according to an example embodiments of the present inventive concept;

FIG. 5 is a diagram illustrating a recess of a marking metallic layer included in a semiconductor package according to example embodiments of the present inventive concept;

FIG. 6 is an enlarged example diagram illustrating part M of FIG. 1 according to an example embodiment of the present inventive concept;

FIG. 7 is a diagram illustrating an example of a base metallic layer included in a semiconductor package according to example embodiments of the present inventive concept; and

FIGS. 8, 9, 10, 11, 12, 13, 14 and 15 are diagrams illustrating a process of forming a semiconductor package according to example embodiments of the present inventive concept.

### DETAILED DESCRIPTION OF THE EMBODIMENTS

It is to be understood that terms or words that are used in the present disclosure and the accompanying claims are not to be limited to general definitions or dictionary definitions. The terms and words are to be construed under a principle that an inventor may appropriately define a concept of a term to describe their invention in the best way. Thus, since example embodiments described in the present disclosure and configurations illustrated in the accompanying drawings are example embodiments and do not represent all of the technical spirit of the present inventive concept, it should be understood that various equivalents and modifications that may replace the example embodiments and configurations may be present within the present disclosure.

In the specification and figures, like reference numerals may denote like elements or features, and thus, repetitive descriptions may be omitted.

In the following descriptions, terms in a singular form include terms in a plural form unless an apparently and contextually conflicting description is present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

Also, an expression of a first direction (e.g., D1), a second direction (e.g., D2), or a third direction (e.g., D3) may correspond to an X-axis, a Y-axis, or a Z-axis, but the expression of a direction is not always limited thereto. As a definition of one direction (e.g., the first direction) is changed, another direction (e.g., the second direction or the third direction) may be changed to correspond thereto.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section.

Hereinafter, the example embodiments of the present inventive concept will be described with reference to the accompanying drawings. However, the idea of the present inventive concept is not limited to the example embodiments described herein. For example, those skilled in the art who understand the technical concept of the present inventive concept may understand the present inventive concept to include other example embodiments that are included in the spirit and scope of the present inventive concept by means of, for example, addition, change, removal, modification or the like of an element or feature.

In the drawings, various thicknesses, lengths, and angles are shown and while the arrangement shown does indeed represent an example embodiment of the present inventive concept, it is to be understood that modifications of the various thicknesses, lengths, and angles may be possible within the spirit and scope of the present inventive concept, and the present inventive concept is not necessarily limited to the particular thicknesses, lengths, and angles shown

Example embodiments of the present inventive concept relate to a semiconductor package and its fabrication method, aimed at addressing challenges in integrating multiple chips within a single package while ensuring efficient heat dissipation and high visibility of marking patterns.

According to example embodiments of the present inventive concept, the semiconductor package includes a layered structure with a first redistribution layer including wiring, a first semiconductor chip, and a post for electrical connectivity. Above this structure, a second redistribution layer includes a base metallic layer that supports heat dissipation. The package further includes a marking metallic layer with a recessed marking pattern, increasing visibility and allowing identification of semiconductor information during intermediate fabrication stages.

The package also incorporates a heat emission system with a thermal interface material (TIM) that fills the recess in the marking metallic layer, providing a pathway for effective heat dissipation from the semiconductor chip. A heat block connected to the TIM further facilitates heat transfer, increasing the package's thermal performance.

The fabrication process involves sequential steps to form the redistribution layers, marking patterns, and heat dissipation features. This process may provide, for example, enhanced heat management, visibility for identification, and structural stability.

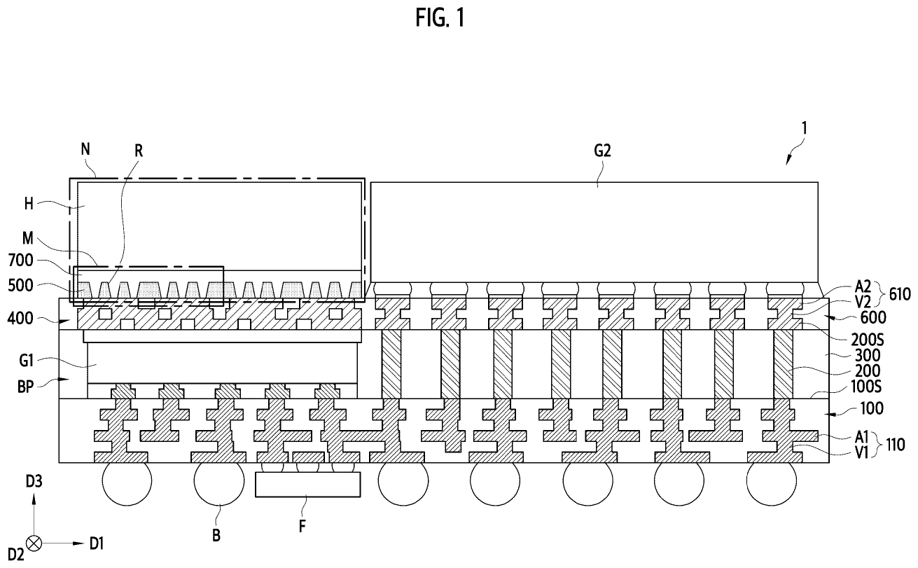

FIG. 1 is a cross-sectional diagram illustrating an example cross section of a semiconductor package 1 according to example embodiments of the present inventive concept.

Referring to FIG. 1, the semiconductor package 1 according to example embodiments of the present inventive concept may be a package-on-package-type semiconductor package in which a plurality of semiconductor packages is stacked to be electrically connected to each other. However, it is merely an example. The semiconductor package 1 according to example embodiments of the present inventive concept may be a system-in-package-type or package-in-package-type semiconductor package in which a plurality of semiconductor chips or a plurality of package substrates is electrically connected in one package and may also include various semiconductor packages in addition to the above-described packages. Hereinafter, to assist in understanding, an example in which the semiconductor package 1, according to example embodiments of the present inventive concept, is the package-on-package-type semiconductor package will be described.

Referring to FIG. 1, the semiconductor package 1 according to example embodiments of the present inventive concept may include a first redistribution layer 100, a first semiconductor chip G1, a post 200, a second redistribution layer 600, a marking metallic layer 500, a heat transfer part 700, and a heat block H.

The first redistribution layer 100 according to example embodiments of the present inventive concept may include first wiring 110. The first redistribution layer 100 may include an insulation layer. The first wiring 110 may be disposed in the insulation layer. For example, a plurality of insulation layers may be stacked in the first redistribution layer 100. The first wiring 110 may include a plurality of wiring patterns A1 and a plurality of vias V1 that vertically connects each wiring pattern A1 to each other. For example, the plurality of vias V1 may penetrate the plurality of insulation layers to connect the wiring patterns A1 to each other. The first wiring 110 may include an insulation material. For example, the first wiring 110 may include at least one of gold (Au), silver (Ag), copper (Cu), nickel (Ni), and/or aluminum (Al).

The first semiconductor chip G1 according to example embodiments of the present inventive concept may be a logic chip disposed on an upper surface 100S of the first redistribution layer 100. For example, the first semiconductor chip G1 may include conductive elements (e.g., bumps or pads) that are disposed on a lower surface thereof. For example, the first semiconductor chip G1 may be electrically connected to the first wiring 110. For example, the first semiconductor chip G1 may include a microprocessor, an analog element, or a digital signal processor. For example, the logic chip may be the microprocessor, the analog element, or the digital signal processor, such as a central processing unit (CPU), a graphic processing unit (GPU), or an application processor (AP). However, the first semiconductor chip G1 is not limited to the above-described example and may include a system-on-chip (SOC) that integrates all required elements of a system, such as a memory chip, an image chip including a charged coupled device (CCD) image sensor or a complementary metal oxide semiconductor (CMOS) image sensor, a microprocessor, a memory, and/or an input/output interface, in one chip. Here, the memory chip may include a volatile memory chip such as a dynamic random access memory (DRAM) or a static random access memory (SRAM) or a non-volatile memory chip such as a phase-change random access memory (PRAM), a magnetoresistive random access memory (MRAM), a ferroelectric random access memory (FeRAM), or a resistive random access memory (RRAM).

The post 200 according to example embodiments of the present inventive concept may be disposed on the upper surface 100S of the first redistribution layer 100. The post 200 may be asymmetrically disposed around the first semiconductor chip G1 in a direction parallel to the first redistribution layer 100 (e.g., any direction on a plane parallel to a plane that is defined by a first direction D1 and a second direction D2 that intersects the first direction D1). However, the present inventive concept is not limited thereto, and in an example embodiment of the present inventive concept, the post 200 may be symmetrically disposed around the first semiconductor chip G1 in a direction parallel to the first redistribution layer 100. The post 200 may be disposed to be spaced apart from the first semiconductor chip G1 in a direction parallel to the upper surface 100S of the first redistribution layer 100. The post 200 may be electrically connected to the first wiring 110. The post 200 may include a conductive material such as copper (Cu), nickel (Ni), silver (Ag), gold (Au), iron (Fe), or a combination thereof. The post 200 may be formed by a plating process.

The second redistribution layer 600 according to example embodiments of the present inventive concept may be disposed on an upper surface 200S1 of the post 200. The second redistribution layer 600 may be disposed on an upper surface of a molding member 300 that will be described below. The second redistribution layer 600 may include a second wiring 610 and a base metallic layer 400. The second redistribution layer 600 may include an insulation layer. For example, a plurality of insulation layers may be stacked in the second redistribution layer 600. The second wiring 610 may include a plurality of wiring patterns A2 and a plurality of vias V2 that vertically connects each wiring pattern A2 to each other. For example, the plurality of vias V2 may penetrate the plurality of insulation layers to connect the plurality of wiring patterns A2 to each other. The second wiring 610 may be electrically connected to the post 200 and the first wiring 110. Another description or additional description of the second wiring 610 may be substituted with or provided by the above-description of the first wiring 110. The base metallic layer 400 may be disposed on the first semiconductor chip G1. The base metallic layer 400 may be formed in an area corresponding to an upper surface of the first semiconductor chip G1 in a direction perpendicular to the first redistribution layer 100 (e.g., a direction parallel to a third direction D3 that is perpendicular to the first direction D1 and the second direction D2). For example, the base metallic layer 400 may overlap the upper surface of the first semiconductor chip G1. In an example embodiment of the present inventive concept, the base metallic layer 400 may be disposed in the second redistribution layer 600. For example, the base metallic layer 400 may be disposed in an insulation layer of the second redistribution layer 600.

The marking metallic layer 500 according to example embodiments of the present inventive concept may be disposed on an upper surface of the base metallic layer 400. The marking metallic layer 500 may be formed in the area corresponding to the upper surface of the first semiconductor chip G1 in the direction perpendicular to the first redistribution layer 100 (e.g., the direction parallel to the third direction D3). The marking metallic layer 500 may include the conductive material such as copper (Cu), nickel (Ni), silver (Ag), gold (Au), iron (Fe), or the combination thereof.

The heat transfer part 700 according to example embodiments of the present inventive concept may be disposed on the marking metallic layer 500. The heat transfer part 700 may include a thermal interface material (TIM).

The heat block H according to example embodiments of the present inventive concept may be connected to the heat transfer part 700 and configured so that heat emission is facilitated. For example, the heat transfer part 700 may be disposed between the base metallic layer 400 and the heat block H and between the marking metallic layer 500 and the heat block H. The heat block H may include a material having excellent thermal conductivity. For example, the heat block H may be formed of silver (Ag), gold (Au), copper (Cu), aluminum (AI), or a combination thereof.

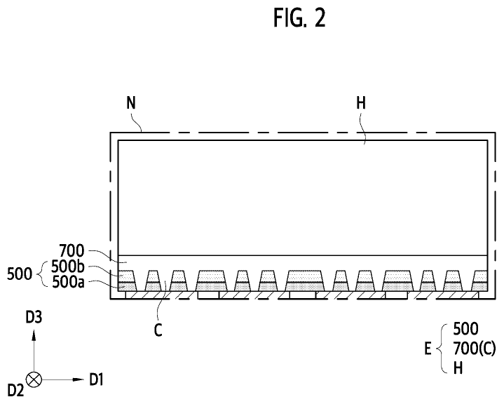

FIG. 2 is an enlarged example diagram illustrating part N of FIG. 1.

Referring to FIG. 2, a heat emission part E according to example embodiments of the present inventive concept may include the marking metallic layer 500, the heat transfer part 700, and the heat block H. Thus, heat generated in the first semiconductor chip G1 may be emitted through the base metallic layer 400 and the heat emission part H. The heat emission part E may overlap the first semiconductor chip G1 in a direction perpendicular to the first redistribution layer 100 (e.g., a direction parallel to the third direction D3). In an example embodiment of the present inventive concept, the heat emission part E does not overlap the post 200 in the direction perpendicular to the first redistribution layer 100 (e.g., the direction parallel to the third direction D3). In such a case, the heat generated in the first semiconductor chip G1 may be emitted through a metal having a high thermal conductivity and a TIM. For example, the metal having the high thermal conductivity and the TIM may continuously extend from the base metallic layer 400, which is positioned on the first semiconductor chip G1, to the heat emission part E, so that the heat may be further effectively emitted from the first semiconductor chip G1. For example, the base metallic layer 400 may be disposed between the first semiconductor chip G1 and the heat block H, and may transmit the heat from the first semiconductor chip G1 to the heat block H.

Referring back to FIG. 1, the semiconductor package 1 according to example embodiments of the present inventive concept may further include the molding member 300, a bump B, a second semiconductor chip G2, and a passive element F.

The molding member 300 according to example embodiments of the present inventive concept may cover the upper surface 100S of the first redistribution layer 100. The molding member 300 may be disposed on the first redistribution layer 100. The molding member 300 may surround the semiconductor chip G1 and the post 200. For example, the molding member 300 may completely surround the first semiconductor chip G1 and the post 200 so that the first semiconductor chip G1 and the post 200 are not exposed to an outside of the molding member 300. For example, the molding member 300 may fill a space between the first semiconductor chip G1 and the post 200.

The molding member 300 according to example embodiments of the present inventive concept may include a thermosetting resin, a thermoplastic resin, an ultraviolet (UV)-curing resin, or a combination thereof. The molding member 300 may include, for example, an epoxy resin, a silicone resin, or a combination thereof. However, this is merely an example, and the molding member 300 may include an epoxy mold compound (EMC).

The bump B according to example embodiments of the present inventive concept may be disposed on a lower surface of the first redistribution layer 100. For example, the bump B may be connected to the first wiring 110. The bump B may include a solder ball or a solder bump. For example, the bump B may have a spherical shape or an oval spherical shape, but the present inventive concept is not limited thereto. The number of bumps B, an interval between the bumps B, disposition or a shape of the bump B, or the like is not limited to an illustration and may also vary depending on a design. The bump B may include, for example, tin (Sn), indium (In), bismuth (Bi), antimony (Sb), copper (Cu), silver (Ag), zinc (Zn), lead (Pb), and a combination thereof, but the present inventive concept is not limited thereto.

The second semiconductor chip G2 according to example embodiments of the present inventive concept may be disposed on an upper surface of the second redistribution layer 600. For example, the second semiconductor chip G2 may include conductive elements (e.g., bumps or pads) that are disposed on a lower surface thereof. The second semiconductor chip G2 may be electrically connected to the second wiring 610. For example, the first semiconductor chip G1 may be an application processor (AP) chip, and the second semiconductor chip G2 may be a memory chip. For example, the second semiconductor chip G2 may be electrically connected to the first semiconductor chip G1 through the second redistribution layer 600, the post 200, and the first redistribution layer 100.

The passive element F according to example embodiments of the present inventive concept may be a resistor, a capacitor, and/or an inductor; however, the present inventive concept is not limited thereto. The passive element F may be connected to the bump B. However, the present inventive concept is not limited thereto. In an example embodiment of the present inventive concept, the passive element F may be connected to the first redistribution layer 100 through a conductive film and might not be disposed on the bump B.

In an example embodiment of the present inventive concept, the passive element F may be electrically connected to the first semiconductor chip G1 and/or the second semiconductor chip G2 through the first redistribution layer 100.

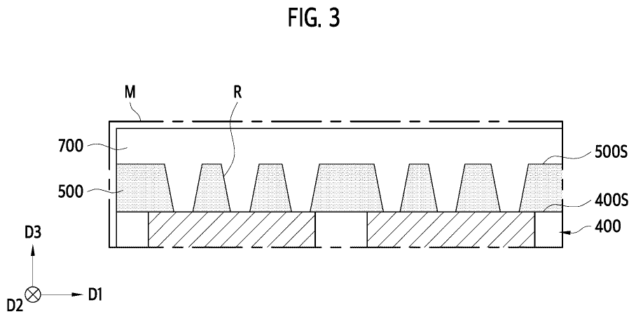

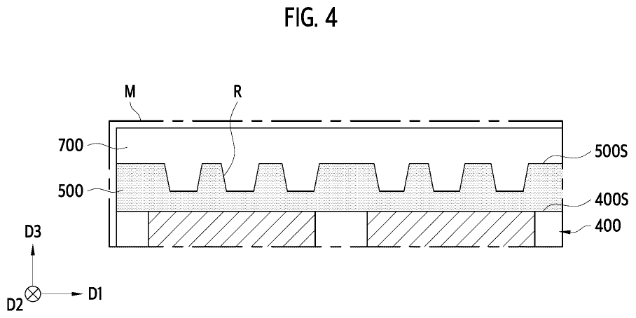

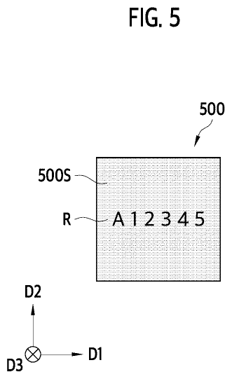

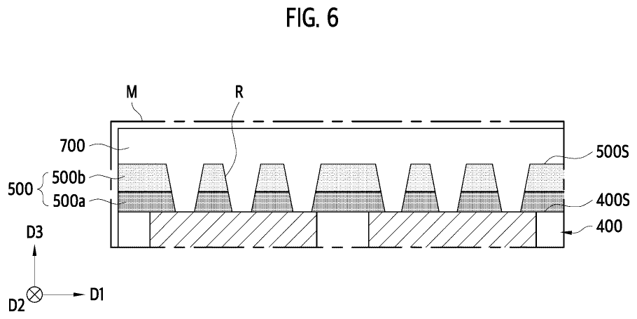

FIG. 3 is an enlarged example diagram illustrating part M of FIG. 1. FIG. 4 is an enlarged example diagram illustrating part M of FIG. 1 according to an example embodiment of the present inventive concept. FIG. 5 is a diagram illustrating a recess R of the marking metallic layer 500 included in the semiconductor package 1 according to example embodiments of the present inventive concept. FIG. 6 is an enlarged example diagram illustrating part M of FIG. 1 according to an example embodiment of the present inventive concept.

FIGS. 3 through 6 are diagrams illustrating various example embodiments of the marking metallic layer 500. The marking metallic layer 500 will be described in detail with reference thereto.

Referring to FIGS. 3 through 6, the marking metallic layer 500 according to example embodiments of the present inventive concept may include the recess R. The recess R may be formed from an upper surface 500S of the marking metallic layer 500 and may extend toward the base metallic layer 400. For example, the recess R may be a marking pattern that is formed into the upper surface 500S of the marking metallic layer 500 by using a laser. The marking pattern may be formed in a combination of a number and a letter for information and/or a formation date of the first semiconductor chip G1 and/or information about the semiconductor package 1, or the like. The recess R may be formed to be engraved on the upper surface 500S of the marking metallic layer 500. For example, the recess R may have a shape recessed from the upper surface 500S of the marking metallic layer 500 toward the base metallic layer 400. However, the recesses R may form the marking pattern that is formed in the combination of at least one number and at least one letter and may be formed to be embossed on the upper surface 500S of the marking metallic layer 500 by a plating process.

The recess R according to example embodiments of the present inventive concept may be formed so that an upper surface 400S of the base metallic layer 400 is exposed through the recess R as illustrated in FIGS. 3 and 6 or so that the upper surface 400S of the base metallic layer 400 is not exposed through the recess R as illustrated in FIG. 4. A width of the recess R may increase in a direction parallel to the upper surface 100s of the first redistribution layer 100 (e.g., any direction on a plane parallel to the plane defined by the first and second directions D1 and D2) as the recess R extends away from the base metallic layer 400. For example, a cross-sectional shape of the recess R may be a trapezoid shape of which an upper side is longer than a lower side.

A shape of the heat transfer part 700 may be determined according to a shape of the recess R according to example embodiments of the present inventive concept. When the recess R is formed to be engraved, the heat transfer part 700 may fill the recess R. For example, when the recess R is formed to be engraved, the heat transfer part 700 may contact the base metallic layer 400 through the recess R. When the recess R is formed to be embossed, the heat transfer part 700 may surround the recess R and may be disposed within the recess R. For example, when the recess R is formed to be embossed, the heat transfer part 700 may be disposed in the recess R but does not contact the base metallic layer 400. Thus, referring back to FIG. 2, the heat emission part E may include a protrusion part C that protrudes toward the base metallic layer 400. The protrusion part C may fill the recess R. A width of the protrusion part C may decrease in the direction parallel to the upper surface 100s of the first redistribution layer 100 (e.g., any direction on the plane parallel to the plane defined by the first and second directions D1 and D2) as the protrusion part C extends toward to the base metallic layer 400. For example, the protrusion part C may be in contact with the base metallic layer 400. For example, the marking metallic layer 500 may at least partially surround the protrusion part C.

Referring to FIG. 6, the marking metallic layer 500 according to example embodiments of the present inventive concept may include a first metallic layer 500a and a second metallic layer 500b. The first metallic layer 500a may be disposed on the upper surface 400S of the base metallic layer 400. For example, the first metallic layer 500a may include a conductive material such as copper. The first metallic layer 500a may have a thickness of about 200 nanometers (nm). The second metallic layer 500b may be disposed on an upper surface of the first metallic layer 500a. For example, the second metallic layer 500b may include a conductive material such as titanium (Ti). The second metallic layer 500b may have a thickness of about 80 nm. The first metallic layer 500a and the second metallic layer 500b may be formed of different materials.

According to such a configuration of the present inventive concept, visibility of the marking pattern may be increased when the recess R is formed in a metallic layer, compared to when the recess R is formed in an insulation layer. For example, after the recess R which is formed to the marking metallic layer 500 of a lower package BP, which includes only the first semiconductor chip G1, is recognized in a fabrication process of the semiconductor package 1, the second semiconductor chip G2, the heat transfer part 700, and the heat block H may be assembled. For example, when the fabrication process of the semiconductor package 1 is performed at a plurality of places or not performed at a single time, fabrication up to the lower package BP in which the recess R is formed in the marking metallic layer 500 may be a priority. Fabrication of the entire semiconductor package 1 may be completed by recognizing the recess R of the marking metallic layer 500 of the lower package BP to acquire information about the lower package BP, and then assembling the second semiconductor chip G2, the heat transfer part 700, and the heat block H, which are suitable for forming the entire semiconductor package 1. In such a fabrication process, the recess R may be filled again with the heat transfer part 700 and used as a passage through which heat generated in the first semiconductor chip 1 may be emitted.

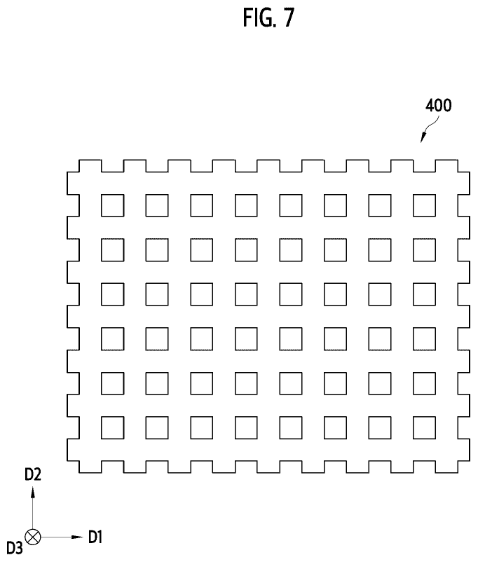

FIG. 7 is a diagram illustrating an example of the base metallic layer 400 included in the semiconductor package 1 according to example embodiments of the present inventive concept.

Referring to FIG. 7, the base metallic layer 400 according to example embodiments of the present inventive concept may have a form of a grid. For example, the base metallic layer 400 may have first portions extending in the first direction D1 and second portions extending in the second direction D2 intersecting the first portions. The base metallic layer 400 may be formed as one grid-shaped layer or formed by overlapping a plurality of grid-shaped layers. When a semiconductor package has an asymmetrical structure around a first semiconductor chip, structural stability may be decreased. For example, when a metallic layer disposed to the second redistribution layer 600 has an asymmetrical structure in a direction parallel to the second redistribution layer 600 (e.g., any direction on a plane parallel to a plane defined by the first direction D1 and the second direction D2), a degree of expansion by heat may be different for each portion, so that a crack may occur in the semiconductor package.

However, according to example embodiments of the present inventive concept, the base metallic layer 400 may be formed in the form of the grid, and through this, a volume or weight of the base metallic layer 400 compared to a volume or weight of an entire metallic layer disposed in the second redistribution layer 600 may be reduced, so that a structural defect due to the asymmetrical structure may be minimized.

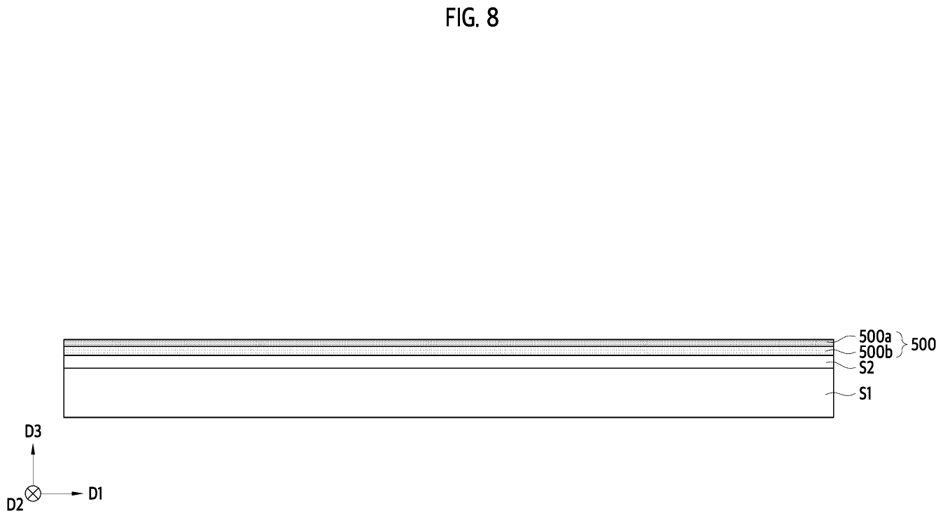

FIGS. 8 through 15 are diagrams illustrating a process of forming the semiconductor package 1 according to example embodiments of the present inventive concept.

FIG. 8 is a diagram illustrating a shape in which the marking metallic layer 500 is formed on a surface of a glass carrier S1. A release layer S2 may be included between the glass carrier S1 and the marking metallic layer 500. The release layer S2 may be physically or chemically stimulated to be separated from the glass carrier S1. For example, when exposed to UV laser light, the release layer S2 may burn or disintegrate, so that the glass carrier S1 may be separated from the marking metallic layer 500. The marking metallic layer 500 may include the first metallic layer 500a and the second metallic layer 500b. For example, the second metallic layer 500b may include titanium to secure deposition strength between the release layer S2 and the first metallic layer 500a.

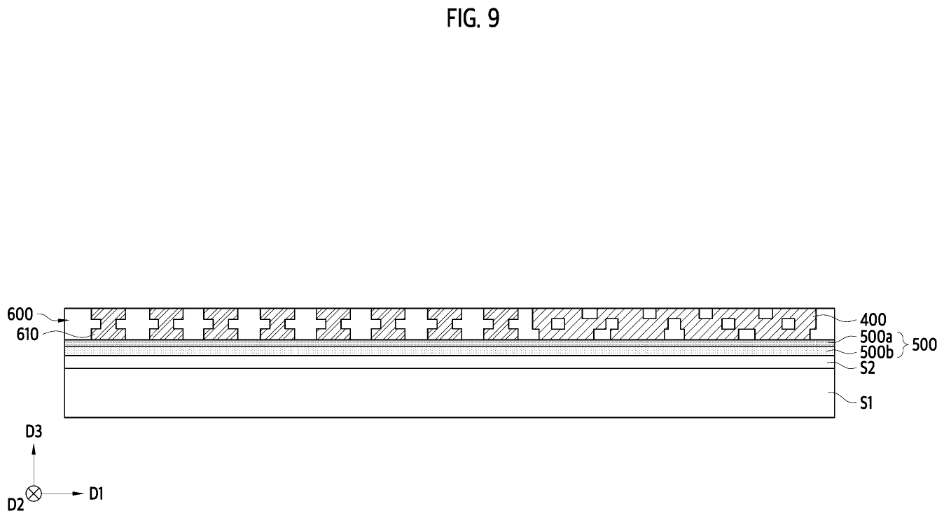

FIG. 9 is a diagram illustrating a shape in which an upper redistribution layer 600 is formed on a surface of the marking metallic layer 500. The upper redistribution layer 600 may be positioned on the first semiconductor chip G1 in a final product of the semiconductor package 1 (see FIG. 1). In addition, the upper redistribution layer 600 may be identical to the above-described second redistribution layer 600. The upper redistribution layer 600 may include upper wiring 610 and the base metallic layer 400. The upper wiring 610 may be identical to the above-described second wiring 610.

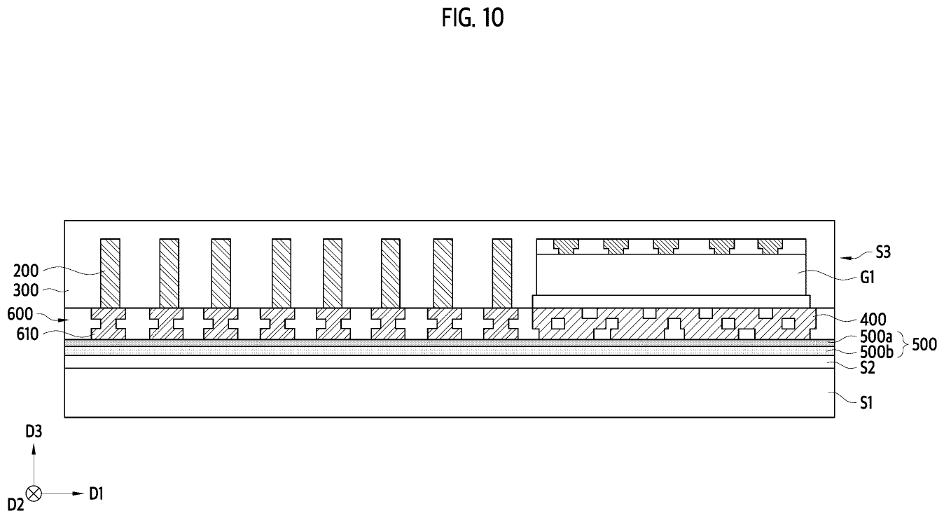

FIG. 10 is a diagram illustrating a shape in which a semiconductor chip layer S3 is formed on a surface of the upper redistribution layer 600. The semiconductor chip layer S3 may include the post 200, the first semiconductor chip G1, and the molding member 300. The post 200 which is connected to the upper wiring 610 may be formed on an upper surface of the upper redistribution layer 600 by a plating process. The first semiconductor chip G1 may be attached to the base metallic layer 400 in a state of being placed on a semiconductor chip attaching film that is on the upper surface of the upper redistribution layer 600. When the post 200 and the first semiconductor chip G1 are formed to the upper redistribution layer 600, the molding member 300 may be formed.

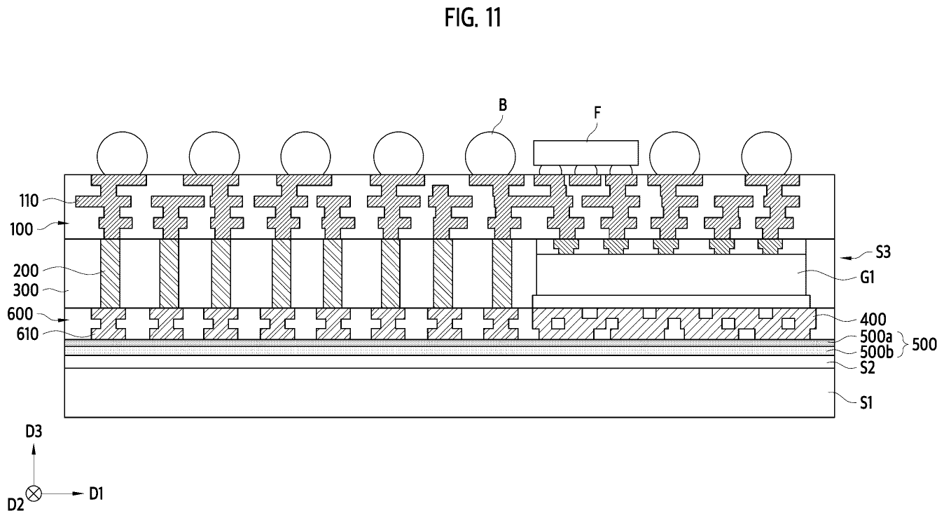

FIG. 11 is a diagram illustrating a shape in which a lower redistribution layer 100 is formed on a surface of the semiconductor chip layer S3. The lower redistribution layer 100 may be positioned below the first semiconductor chip G1 in the final product of the semiconductor package 1 (see FIG. 1). In addition, the lower redistribution layer 100 may be identical to the above-described first redistribution layer 100. The lower redistribution layer 100 may include lower wiring 110, which may be identical to the above-described first wiring 110. After formation of the lower redistribution layer 100 ends, the bump B may be formed on an upper surface of the lower redistribution layer 100, and the passive element F may be coupled thereto.

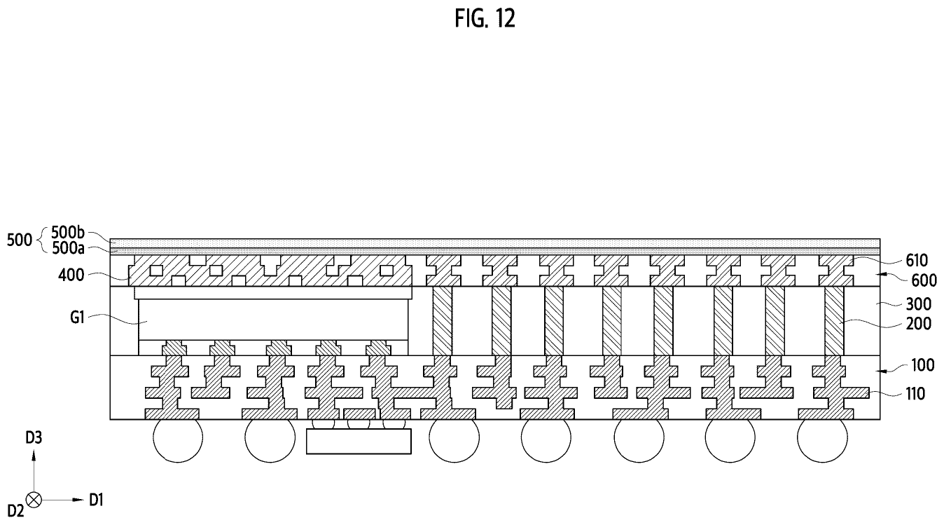

FIG. 12 is a diagram illustrating a shape in which the glass carrier S1 is removed after the glass carrier S1 is turned upside down so as to be positioned above. A plurality of layers described through FIGS. 7 through 10 may be turned upside down, and the marking metallic layer 500 and the glass carrier S1 may be separated from each other by using the release layer S2.

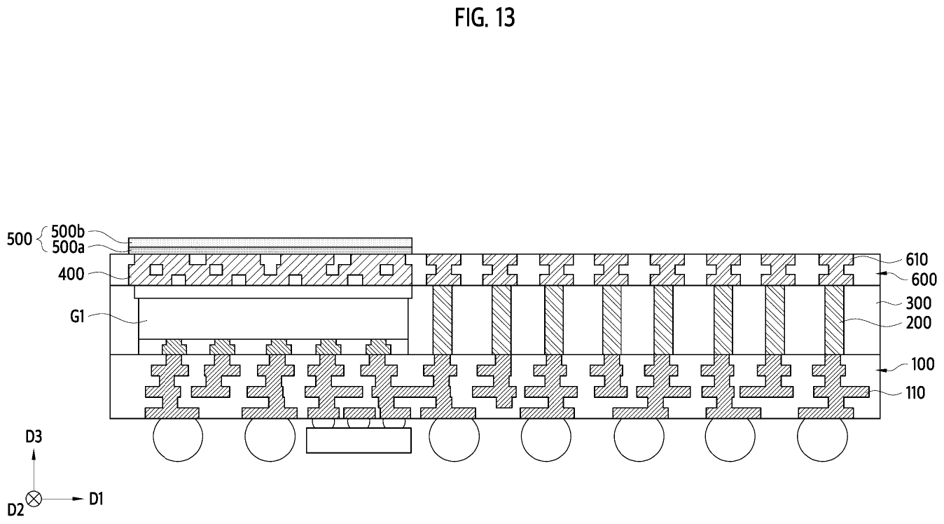

FIG. 13 is a diagram illustrating a state in which the marking metallic layer 500 is formed so as to overlap the first semiconductor chip G1 in a direction perpendicular to the upper redistribution layer 600 (e.g., a direction parallel to the third direction D3). That is, the marking metallic layer 500 which has been disposed on the entire upper surface of the upper redistribution layer 600 may be removed in an area except an area overlapping the first semiconductor chip G1 in the direction perpendicular to the upper redistribution layer 600 (e.g., the direction parallel to the third direction D3).

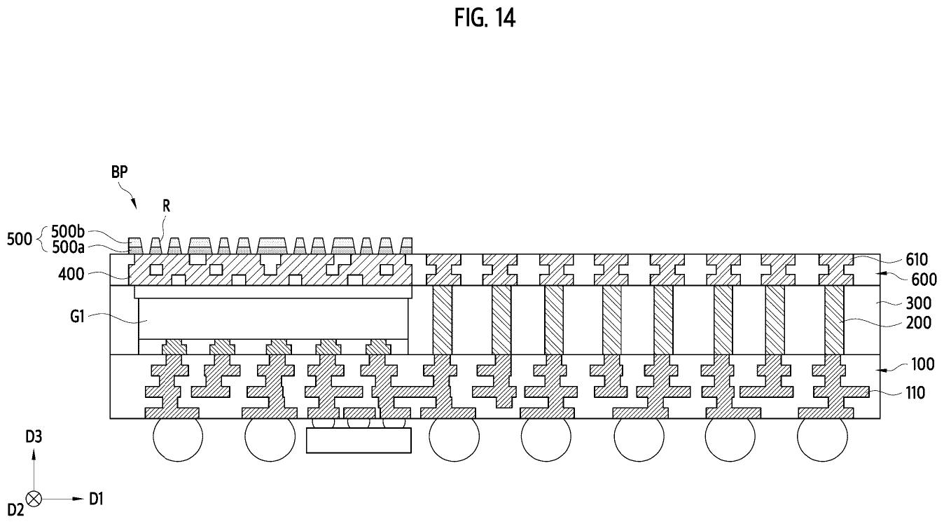

FIG. 14 is a diagram illustrating a shape in which the recess R is formed from another surface of the marking metallic layer 500 toward the base metallic layer 400. As illustrated in FIG. 14, a semiconductor package formed up to formation of the recess R may be defined as the lower package BP. The recess R which is formed in the marking metallic layer 500 may be formed to show a combination of a number and a letter to include information and/or a formation date of the first semiconductor chip G1 and/or information about the lower package BP, or the like. Information on the second semiconductor chip G2 which is suitable for the entire semiconductor package 1 may be acquired by recognizing the recess R.

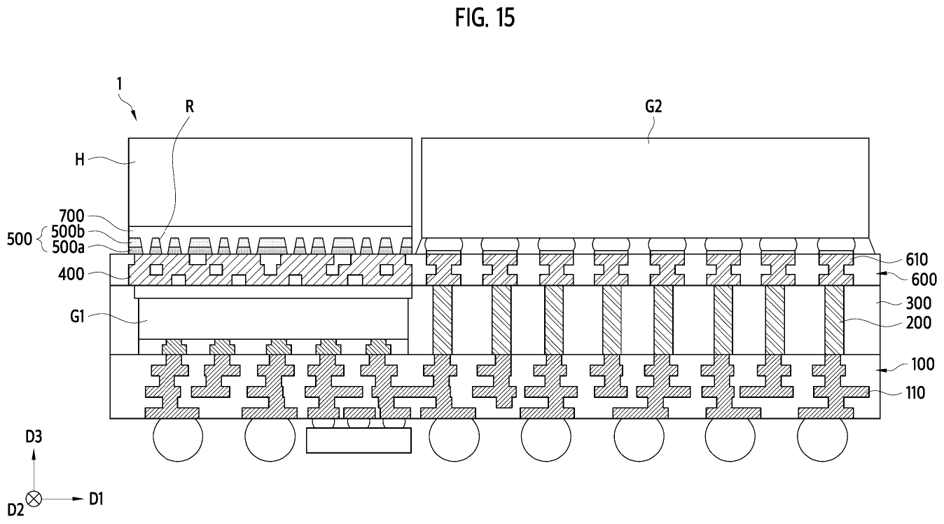

FIG. 15 is a diagram illustrating a shape in which the heat emission part E (see FIG. 2) and the second semiconductor chip G2 are connected to the lower package BP. After the information about the second semiconductor chip G2 suitable for the entire semiconductor package 1 is identified by recognizing the recess R of the marking metallic layer 500 of the lower package BP, the recess R may be filled with the heat transfer part 700 which includes a TIM. Afterward, the heat block H, which is connected to the heat transfer part 700 and configured so that heat emission is facilitated, may be formed to the lower package BP. In addition, the semiconductor chip G2 which is electrically connected to the upper wiring 610 may be formed to the lower package BP.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a first redistribution layer comprising a first wiring;
a first semiconductor chip disposed on the first redistribution layer;
a post disposed on the first redistribution layer, and spaced apart from the first semiconductor chip in a direction parallel to an upper surface of the first redistribution layer, wherein the post is electrically connected to the first wiring;
a second redistribution layer disposed on the post and comprising a second wiring and a base metallic layer, wherein the second wiring is electrically connected to the post, and the base metallic layer is disposed on the first semiconductor chip;
a marking metallic layer disposed on an upper surface of the base metallic layer; and
a heat transfer part disposed on an upper surface of the marking metallic layer and comprising a thermal interface material (TIM),
wherein the marking metallic layer comprises a recess that is formed from the upper surface of the marking metallic layer toward the base metallic layer, and
the heat transfer part fills the recess.

2. The semiconductor package of claim 1, wherein the base metallic layer and the marking metallic layer overlap the first semiconductor chip in a direction perpendicular to the first redistribution layer.

3. The semiconductor package of claim 1, wherein the base metallic layer has a form of a grid.

4. The semiconductor package of claim 1, wherein the post is disposed adjacent to the first semiconductor chip in a direction parallel to the first redistribution layer.

5. The semiconductor package of claim 1, wherein, in the direction parallel to the upper surface of the first redistribution layer, a width of the recess increases as the recess extends away from the base metallic layer.

6. The semiconductor package of claim 5, wherein the upper surface of the base metallic layer is exposed through the recess.

7. The semiconductor package of claim 1, wherein the marking metallic layer comprises:
a first metallic layer disposed on the upper surface of the base metallic layer and comprising copper; and
a second metallic layer disposed on an upper surface of the first metallic layer and comprising titanium.

8. The semiconductor package of claim 1, further comprising a molding member configured to cover the upper surface of the first redistribution layer, to surround the first semiconductor chip and the post, and to fill a space between the first semiconductor chip and the post.

9. The semiconductor package of claim 1, wherein the heat transfer part is in contact with the base metallic layer through the recess.

10. The semiconductor package of claim 8, further comprising:
a heat block connected to the heat transfer part and configured so that heat emission is facilitated; and
a second semiconductor chip disposed on an upper surface of the second redistribution layer and electrically connected to the second wiring.

11. A semiconductor package comprising:
a first redistribution layer comprising a first wiring;
a first semiconductor chip disposed on an upper surface of the first redistribution layer;
a post disposed on the upper surface of the first redistribution layer, and spaced apart from the first semiconductor chip in a direction parallel to the upper surface of the first redistribution layer, wherein the post is electrically connected to the first wiring;
a second redistribution layer disposed on an upper surface of the post and comprising a second wiring and a base metallic layer, wherein the second wiring is electrically connected to the post, and the base metallic layer is disposed on the first semiconductor chip; and
a heat emission part comprising a protrusion part configured to protrude toward the base metallic layer.

12. The semiconductor package of claim 11,
wherein the heat emission part comprises:
a marking metallic layer configured to at least partially surround the protrusion part;
a heat transfer part disposed on the marking metallic layer and comprising the protrusion part and a thermal interface material (TIM); and
a heat block connected to the heat transfer part and configured so that heat emission is facilitated.

13. The semiconductor package of claim 12, wherein, in the direction parallel to the upper surface of the first redistribution layer, a width of the protrusion part decreases as the protrusion part extends toward the base metallic layer.

14. The semiconductor package of claim 12, wherein the protrusion part is in contact with the base metallic layer.

15. The semiconductor package of claim 11, wherein the heat emission part is configured to:
overlap the first semiconductor chip in a direction perpendicular to the first redistribution layer; and
not overlap the post.

16. The semiconductor package of claim 11, wherein the base metallic layer has a form of a grid.

17. The semiconductor package of claim 16, wherein the post is asymmetrically disposed around the first semiconductor chip in a direction parallel to the first redistribution layer.

18. The semiconductor package of claim 12, wherein the marking metallic layer comprises:
a first metallic layer disposed on an upper surface of the base metallic layer; and
a second metallic layer disposed on an upper surface of the first metallic layer and formed of a material that is different from a material of the first metallic layer.

19. A semiconductor package fabricating method comprising:
forming a marking metallic layer on a surface of a glass carrier;
forming an upper redistribution layer on a first surface of the marking metallic layer, wherein the upper redistribution layer comprises upper wiring and a base metallic layer;
forming a semiconductor chip layer on a surface of the upper redistribution layer, wherein the semiconductor chip layer comprises a post, a first semiconductor chip, and a molding member;
forming a lower redistribution layer that comprises lower wiring electrically connected to the upper wiring, the first semiconductor chip, and the post and is disposed on a surface of the semiconductor chip layer;
removing the glass carrier with turning the glass carrier upside down so that the glass carrier is positioned above; and
forming a recess that extends from a second surface of the marking metallic layer toward the base metallic layer.

20. The semiconductor package fabricating method of claim 19, after the forming of the recess, further comprising:
recognizing the recess;
forming a heat emission part comprising a heat transfer part and a heat block, wherein the heat transfer part is disposed on the second surface of the marking metallic layer and comprises a thermal interface material (TIM) configured to fill the recess, wherein the heat block is connected to the heat transfer part and configured so that heat emission is facilitated; and
forming a second semiconductor chip on another surface of the upper redistribution layer and electrically connected to the upper wiring.
